(19) United States
(12) Patent Application Publication
(10) Pub. No.: US 2008/0284542 A1
(43) Pub. Date: Nov. 20, 2008

(54) FILM BULK ACOUSTIC RESONATOR

(75) Inventors: Kenya Sano, Kanagawa-ken (JP); Masahiko Hasunuma, Kanagawa-ken (JP); Hiroshi Toyoda, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/923,117

(22) Filed: Oct. 24, 2007

(30) Foreign Application Priority Data
Oct. 25, 2006 (JP) 2006-290314

(51) Int. Cl. H03H 9/15

(52) U.S. Cl. 333/187

(57) ABSTRACT

A film bulk acoustic resonator includes: a substrate; a lower electrode held on the substrate with at least a portion thereof being in a hollow state; a piezoelectric film provided on the lower electrode; and an upper electrode provided on the piezoelectric film. At least one of the lower electrode and the upper electrode is primarily composed of copper (Cu) and further contains a first element having a negatively larger free energy of oxide formation (ΔG) than copper. At least one of the lower electrode and the upper electrode is primarily composed of copper (Cu) and further contains a second element having smaller surface energy than copper.

### CROSS-REFERENCE TO RELATED APPLICATIONS

This application is based upon and claims the benefit of priority from the prior Japanese Patent Application No. 2006-290314, filed on Oct. 25, 2006; the entire contents of which are incorporated herein by reference.

### BACKGROUND OF THE INVENTION

1. Field of the Invention

This invention relates to a film bulk acoustic resonator.

2. Background Art

With the growing performance and functionality of recent mobile radio terminals, the number of components used in a mobile radio terminal has been significantly increased, and it is important to downsize and modularize the components. Among radio circuits, the filter particularly occupies much space. Hence, to downsize the radio circuits and to reduce the number of components, the filter needs to be downsized and modularized.

Conventionally used filters include dielectric filters, surface acoustic wave (SAW) filters, and LC filters, for example. Recently, film bulk acoustic resonator (FBAR) filters have been considered to be most promising for downsizing and modularizing the filters.

A film bulk acoustic resonator comprises an upper electrode, a lower electrode, a piezoelectric film sandwiched between the upper electrode and the lower electrode, and a cavity provided below the lower electrode.

The material of the upper electrode and the lower electrode of such a film bulk acoustic resonator requires low electric resistance and good orientation.

Hence a technique for using copper (Cu) in the upper electrode and the lower electrode is proposed (e.g., JP-A 2003-204239 (Kokai)).

However, this technique does not take into consideration the poor adhesion of copper (Cu) and its property of being easily oxidized, and fails to prevent degradation of filter characteristics caused thereby.

### SUMMARY OF THE INVENTION

According to an aspect of the invention, there is provided a film bulk acoustic resonator including: a substrate; a lower electrode held on the substrate with at least a portion thereof being in a hollow state; a piezoelectric film provided on the lower electrode; and an upper electrode provided on the piezoelectric film, at least one of the lower electrode and the upper electrode being primarily composed of copper (Cu) and further containing a first element having a negatively larger free energy of oxide formation (ΔG) than copper.

According to an aspect of the invention, there is provided a film bulk acoustic resonator including: a substrate; a lower electrode held on the substrate with at least a portion thereof being in a hollow state; a piezoelectric film provided on the lower electrode; and an upper electrode provided on the piezoelectric film, at least one of the lower electrode and the upper electrode being primarily composed of copper (Cu) and further containing a second element having smaller surface energy than copper.

### BRIEF DESCRIPTION OF THE DRAWINGS

FIG. 1 is a schematic cross-sectional view for illustrating a film bulk acoustic resonator according to the embodiment of the invention.

FIGS. 2A and 2B show schematic views for illustrating the effect of acoustic impedance in the lower electrode and the upper electrode.

FIG. 3 shows a table for describing the relationship between acoustic impedance and electric resistance (specific resistance) of various electrode materials.

FIG. 4 is a graph for illustrating free energy of oxide formation (ΔG).

FIG. 5 is a schematic view for illustrating the formation of selective oxide coating.

FIG. 6 is a schematic view for illustrating the relationship between surface energy and wettability.

FIGS. 7A to 7E are schematic process cross-sectional views for illustrating the method for manufacturing a film bulk acoustic resonator according to the embodiment of the invention.

FIG. 8 is a schematic view for illustrating the film bulk acoustic resonator including a holly cavity.

### DETAILED DESCRIPTION OF THE INVENTION

An embodiment of the invention will now be described with reference to the drawings.

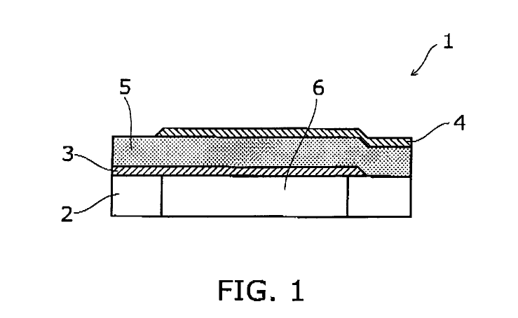

FIG. 1 is a schematic cross-sectional view for illustrating a film bulk acoustic resonator 1 according to the embodiment of the invention.

As illustrated in FIG. 1, for example, on the upper surface of a substrate 2 of the film bulk acoustic resonator 1, a thermal oxide film, not shown, an amorphous buffer layer, not shown, a lower electrode 3, a piezoelectric film 5, and an upper electrode 4 are formed in this order from below. The substrate 2 includes a cavity 6 passing therethrough, and the lower electrode 3 covers the substrate upside opening of the cavity 6. The upper electrode 4 is opposed to the lower electrode 3, and the piezoelectric film 5 is provided between the lower electrode 3 and the upper electrode 4.

Example materials of each component are as follows. The substrate 2 can be made of silicon (Si). The thermal oxide film, not shown, can be made of silicon oxide (SiO₂). The buffer layer, not shown, can be an amorphous buffer layer made of TiAl or tantalum aluminum (TaAl), or can be made of aluminum nitride (AlN). The piezoelectric film 5 can be made of aluminum nitride (AlN). The lower electrode 3 and the upper electrode 4 can be made of copper (Cu) doped with a prescribed element. The material of the lower electrode 3 and the upper electrode 4 is described later in detail.

The film bulk acoustic resonator 1 has a function of filtering an input signal using the piezoelectric effect of the piezoelectric film 5. A signal inputted to an input terminal, not shown, is passed through the upper electrode 4 connected to the input terminal (not shown) and through the piezoelectric film 5 and outputted to the lower electrode 3. At this time, the piezoelectric film 5 vibrates along its thickness due to the inverse piezoelectric effect. Because the laminated body composed of the upper electrode 4, the piezoelectric film 5, and the lower electrode 3 has a definite resonance frequency for vibration occurring in the piezoelectric film 5, only the signal component matching this resonance frequency among the inputted signal components is outputted. Hence a resonator filter can be configured by using at least two or more film bulk acoustic resonators 1 having such filtering function in series-parallel connection.

Next, the material of the lower electrode 3 and the upper electrode 4 is described.

First, use of copper (Cu) in the lower electrode 3 or the upper electrode 4 is described.

To improve the characteristics of the film bulk acoustic resonator 1, the strain energy of excited acoustic waves needs to be confined in the piezoelectric film 5 serving as the resonant portion. This can be achieved by selecting a material having higher acoustic impedance as the material of the lower electrode 3 or the upper electrode 4. This is because, with the increase of the difference in acoustic impedance between two media propagating acoustic waves, reflection at the interface therebetween increases and leakage therethrough decreases.

For example, if a low acoustic impedance material such as aluminum (Al) is used in the lower electrode 3 or the upper electrode 4, damping due to leakage of the strain energy of acoustic waves occurs. This results in decreasing the electromechanical coupling coefficient k² and the quality factor Q-value, degrading the characteristics of the film bulk acoustic resonator 1.

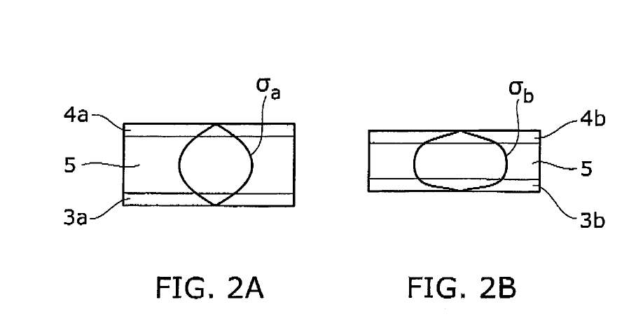

FIGS. 2A and 2B show schematic views for illustrating the effect of acoustic impedance in the lower electrode and the upper electrode.

FIG. 2A is a schematic view for illustrating the effect of using a low acoustic impedance material in the lower electrode 3 and the upper electrode 4. FIG. 2B is a schematic view for illustrating the effect of using a high acoustic impedance material in the lower electrode 3 and the upper electrode 4.

As shown in FIG. 2A, the vibration caused by the inverse piezoelectric effect of the piezoelectric film 5 is reflected by the lower electrode 3a and the upper electrode 4a and confined in the piezoelectric film 5. However, the strain energy of acoustic waves leaks outside through the lower electrode 3a and the upper electrode 4a made of a low acoustic impedance material. This results in decreasing the strain energy of acoustic waves confined in the piezoelectric film 5. The distribution of stress σₐ in FIG. 2A is intended for visually illustrating this situation by using stress σₐ, which is easily measured.

On the other hand, as shown in FIG. 2B, the vibration caused by the inverse piezoelectric effect of the piezoelectric film 5 is reflected by the lower electrode 3b and the upper electrode 4b and confined in the piezoelectric film 5. Here, the lower electrode 3b and the upper electrode 4b made of a high acoustic impedance material have large interfacial reflection, and the strain energy of acoustic waves leaking outside is small. Consequently, the decrease of the strain energy of acoustic waves confined in the piezoelectric film 5 is held down. The distribution of stress σ_{b} in FIG. 2B is intended for visually illustrating this situation. That is, as compared with the distribution of stress σₐ in FIG. 2A, the value of stress σ_{b} in the piezoelectric film 5 is increased with a uniform distribution, showing that more strain energy of acoustic waves is confined.

Here, elements affecting the quality factor Q-value at the resonance point include elastic loss in the piezoelectric film 5, the lower electrode 3, and the upper electrode 4, and series resistance. Elements affecting the quality factor Q-value at the antiresonance point include elastic loss in the piezoelectric film 5, the lower electrode 3, and the upper electrode 4, conductance of the substrate 2, and dielectric loss of the piezoelectric film 5.

Hence, to improve the characteristics of the film bulk acoustic resonator 1, the electric loss of the material of the lower electrode 3b and the upper electrode 4b also needs to be considered. Thus it is preferable to select a material having high acoustic impedance and low electric resistance for the lower electrode 3b and the upper electrode 4b.

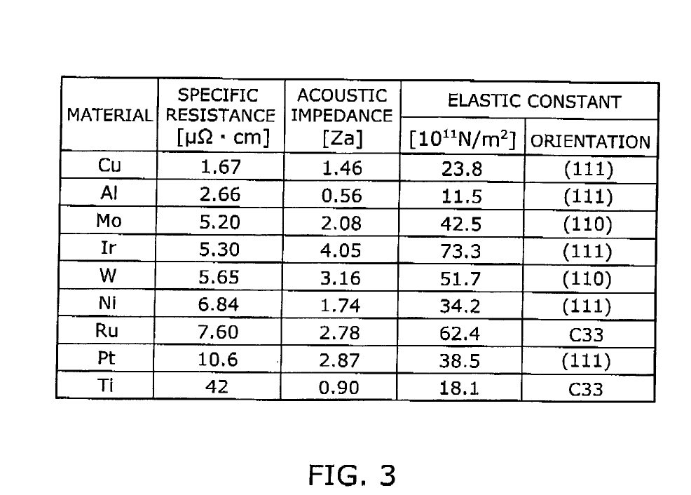

FIG. 3 shows a table for describing the relationship between acoustic impedance and electric resistance (specific resistance) of various electrode materials.

The materials, which are listed in FIG. 3 in the ascending order of specific resistance, include those having relatively low acoustic impedance. Here, if copper (Cu), which has low specific resistance and has an acoustic impedance close to that of molybdenum (Mo), is selected as the electrode material, the selection is effective for improving the characteristics of the film bulk acoustic resonator 1.

More specifically, copper (Cu) has a density of as high as 8.93 g/cm³, and its elastic constant is also high. Hence it has relatively high acoustic impedance and less prone to degradation of piezoelectric resonance characteristics. Furthermore, its specific resistance is 1.69 μΩ·cm, which is even lower than that of aluminum (Al). Hence the decrease of quality factor Q-value at the resonance point, Qr, due to the increase of series resistance can be prevented. Moreover, because it is relatively easily oriented in the <111> direction, the orientation of aluminum nitride (AlN) and zinc oxide (ZnO) serving as the material of the piezoelectric film 5 can be improved.

However, copper (Cu) has high surface energy and poor wettability, hence poor adhesion, with other materials. Furthermore, because its oxide has a negative free energy of formation, it is easily oxidized. Moreover, because the formed oxide film is not dense, there is also a problem of continuous oxidation due to the outward diffusion of copper (Cu) ions through vacancies in the oxide film or continuous inward diffusion of oxygen. Formation of oxide film by electrode oxidation creates a shift of resonance frequency due to the change of film thickness and lamination structure, which causes deviation in the passband of a filter formed by combining the film bulk acoustic resonators 1.

As a result of investigations, the inventor has discovered that doping copper (Cu) with a prescribed element leads to prevention of oxidation and improvement of adhesion.

First, the prevention of oxidation is described.

Oxidation is characterized by free energy of oxide formation (ΔG), which indicates the likelihood of coupling with oxygen.

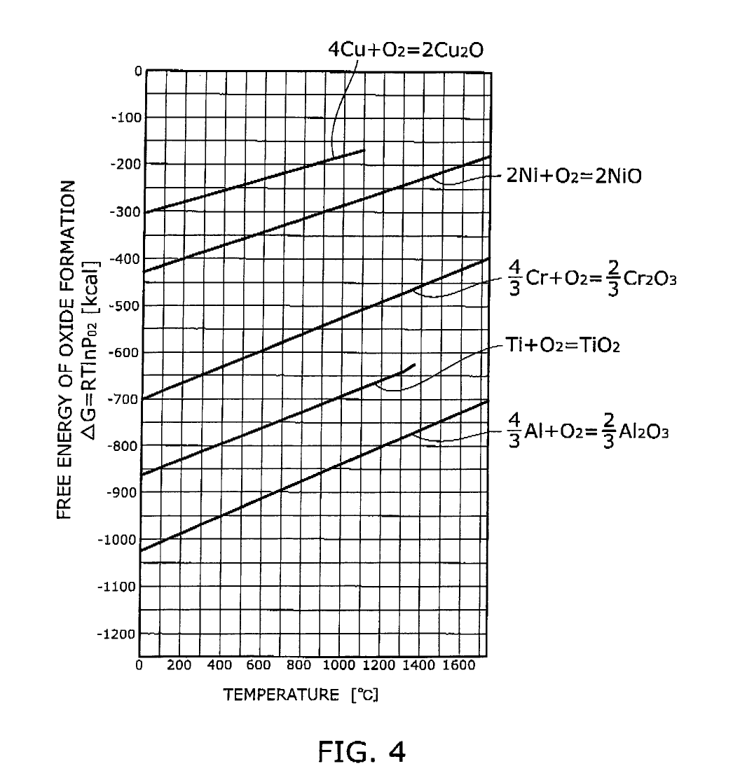

FIG. 4 is a graph for illustrating free energy of oxide formation (ΔG).

As shown in FIG. 4, an element appearing at a lower level is more likely to couple with oxygen, and the resulting oxide is more stable. Hence, if copper (Cu) is doped with an element having smaller (negatively larger) free energy of oxide formation (ΔG) than copper oxide, selective oxide coating can be formed on the surface. This stops further progress of oxidation, and thus oxidation can be prevented.

Example elements having smaller (negatively larger) free energy of oxide formation (ΔG) than copper oxide include aluminum (Al), titanium (Ti), zirconium (Zr), nickel (Ni), chromium (Cr), tantalum (Ta), niobium (Nb), tungsten (W), and molybdenum (Mo).

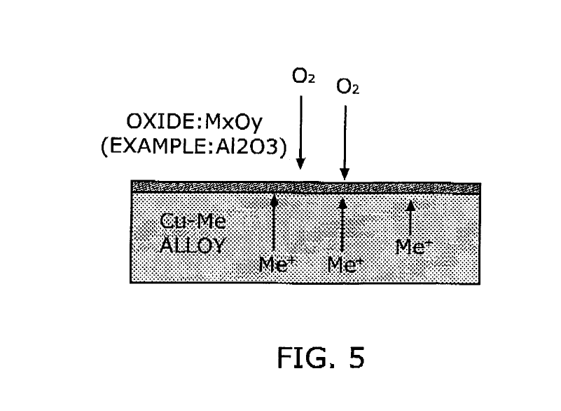

FIG. 5 is a schematic view for illustrating the formation of selective oxide coating.

As shown in FIG. 5, if copper (Cu) is doped with an element Me having smaller (negatively larger) free energy of oxide formation (ΔG) than copper oxide, ions of the element Me selectively undergo outward diffusion and react with oxygen (O₂) in the atmosphere at the surface (electrode surface) to form oxide film (MₓO_{y}, e.g., Al₂O₃ when doped with Al). Oxidation occurring thereafter is oxidation reaction due to diffusion through this oxide film, which itself is stable. Consequently, oxidation of copper (Cu) itself is prevented. Furthermore, if an element forming oxygen-deficient (n-type) oxide is selected, dense oxide can be formed on the surface (electrode surface), and hence diffusion of oxygen (O₂) can be further inhibited. Elements forming oxygen-deficient (n-type) oxide include aluminum (Al), titanium (Ti), zirconium (Zr), nickel (Ni), and chromium (Cr).

Next, the improvement of adhesion is described.

To enhance adhesion at the interface, closeness of energy levels of outermost electrons and overlap of their orbitals are needed. However, the lattice constant and energy level cannot be varied significantly.

As a result of investigations, the inventor has discovered that adhesion can be improved by doping with a prescribed element to control surface energy, thereby improving wettability.

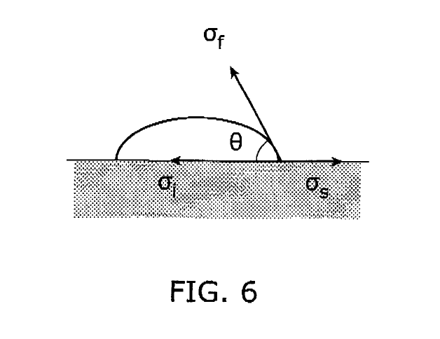

FIG. 6 is a schematic view for illustrating the relationship between surface energy and wettability.

As shown in FIG. 6, the wetting angle θ is determined by the balance among three energies: the surface energy of the substrate, σₛ; the surface energy of copper (Cu) film, σ_{f}; and the interface energy σᵢ. The wetting angle θ is expressed by the following formula:

cos θ=(σₛ−σᵢ)/σ_{f} (1)

Here, considering the case where copper (Cu) is grown on the surface of another material, copper (Cu) has high surface energy σ_{f1} and large wetting angle θ as described above. Therefore it has poor wettability, and hence poor adhesion, with the other material.

As a result of investigations, the inventor has discovered that the surface energy of copper (Cu) film itself, σ_{f2}, can be decreased by doping with an element having lower surface energy than copper (Cu).

More specifically, by doping with an element having lower surface energy than copper (Cu) to decrease the surface energy of copper (Cu) film itself, σ_{f2}, the wetting angle θ decreases as expressed by formula (1), and thus wettability can be improved. If wettability is successfully improved, the number of bonding branches between atoms at the interface increases, and hence adhesion can be improved.

Example elements, which have lower surface energy than copper (Cu) and with which copper (Cu) is to be doped, include zirconium (Zr), aluminum (Al), silicon (Si), and magnesium (Mg).

Prevention of oxidation or improvement of adhesion can be achieved by doping copper (Cu) with a prescribed element. Here, by doping with zirconium (Zr) or aluminum (Al), both the effects of prevention of oxidation and improvement of adhesion can be achieved.

Alternatively, a dopant element for prevention of oxidation and a dopant element for improvement of adhesion can be combined for doping.

The doping amount can be set to 10 at % (atomic percent) or less. In this embodiment, doping is performed in such minute amounts. Hence the effects of prevention of oxidation and improvement of adhesion can be achieved without affecting the basic effects of copper (Cu) such as its high acoustic impedance and low electric resistance.

It is noted that doping with a prescribed element may be performed on one or both of the lower electrode 3 and the upper electrode 4.

As described above, by using copper (Cu) doped with a prescribed element as the electrode material, it is possible to obtain electrodes having good confinement of strain energy of acoustic waves, low electric resistance, and superior in oxidation prevention and adhesion.

Next, a method for manufacturing a film bulk acoustic resonator is illustrated.

For convenience, a description is given of a method for manufacturing a film bulk acoustic resonator including a cavity 6 passing through a substrate 2.

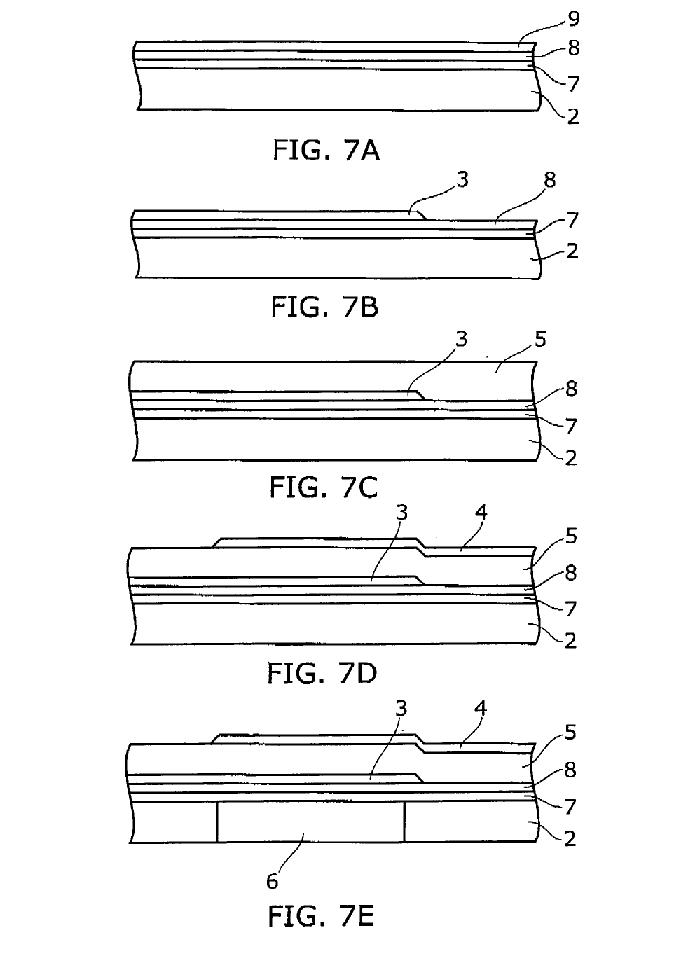

FIGS. 7A to 7E are schematic process cross-sectional views for illustrating the method for manufacturing a film bulk acoustic resonator according to the embodiment of the invention.

First, as shown in FIG. 7A, a thermal oxide film 7 is formed on the upper surface of a <100>-oriented silicon (Si) substrate 2. An amorphous buffer layer 8 illustratively made of TiAl is formed to a thickness of substantially 10 nanometers on the upper surface of the thermal oxide film 7. Furthermore, a copper layer 9 doped with the element described above, for example, a copper-aluminum (Cu—Al) layer doped with 1 at % (atomic percent) aluminum, is formed to a thickness of substantially 200 nanometers on the amorphous buffer layer 8. The formation of these can be performed by sputtering, for example.

The crystal orientation of the Cu—Al film was measured by rocking curve measurement based on X-ray diffraction (XRD). Then the <111> orientation half-width of copper (Cu) was 0.9°. Thus good orientation was successfully confirmed.

Next, as shown in FIG. 7B, the copper layer 9 doped with the element described above is processed into a prescribed electrode configuration to form a lower electrode 3. The formation of the lower electrode 3 can be performed by photolithography or wet etching, for example. In wet etching, a mixed acid of phosphoric acid, nitric acid and acetic acid can be illustratively used.

Next, as shown in FIG. 7C, a piezoelectric film 5 is formed to a thickness of substantially 1.75 micrometers. The piezoelectric film 5 can be illustratively made of aluminum nitride (AlN), and the formation thereof can be performed by DC pulse sputtering. In DC pulse sputtering, a mixed gas of argon (Ar) gas and nitrogen (N₂) gas can be illustratively used, and the substrate temperature can be set to 300° C.

It was confirmed by TEM observation that crystal grains of the aluminum nitride (AlN) film were epitaxially grown on crystal grains of the Cu—Al film (the so-called local epitaxial growth). This is an effect of decreasing the surface energy of copper (Cu) film itself, σ_{f2}, by doping with the prescribed element described above (aluminum (Al) in this case). Furthermore, crystal orientation was measured by rocking curve measurement based on X-ray diffraction (XRD). Then the <0002> orientation half-width of aluminum nitride (AlN) was 1.1°. Thus good orientation was successfully confirmed.

Next, as shown in FIG. 7D, the upper surface of the piezoelectric film 5 is processed into a prescribed configuration by RIE, for example. Then a Cu—Al film having the same composition as the lower electrode 3 described above is formed to a thickness of substantially 250 nanometers. Here, alternatively, a composition different from that of the lower electrode 3 can be also used by changing the dopant element. Subsequently, it is processed into a prescribed electrode configuration to form an upper electrode 4. The formation of the upper electrode 4 can be performed by photolithography or wet etching, for example. In wet etching, a mixed acid of phosphoric acid, nitric acid and acetic acid can be illustratively used.

As needed, for example, the piezoelectric film 5 can be processed by RIE to provide vias for interconnecting the lower electrode 3, and a bonding pad can be provided by forming aluminum (Al) film to a thickness of substantially 1 micrometer.

Next, as shown in FIG. 7E, the backside of the substrate 2 is lapped and polished to a thickness of substantially 200 micrometers, for example, and washed with ethanol or amine-based remover. Then a pattern for forming a cavity 6 is formed by photolithography. Subsequently, a cavity 6 is formed by Deep-RIE, where CF₄ gas and SF₆ gas are alternately introduced for etching. Then the oxide film is removed by wet etching with NH₄F.

The frequency characteristics of the film bulk acoustic resonator thus manufactured was measured. The electromechanical coupling coefficient k² was 7.2%. With regard to the quality factor Q-value, the Q-value at the resonance point (Qr) was 1300, and the Q-value at the antiresonance point (Qa) was 1100. Thus achievement of better characteristics than those based on pure aluminum (Al) electrodes was successfully confirmed.

The embodiment of the invention has been described with reference to examples. However, the invention is not limited to these examples.

Any modifications to the above examples suitably made by those skilled in the art are also encompassed within the scope of the invention as long as they include the features of the invention.

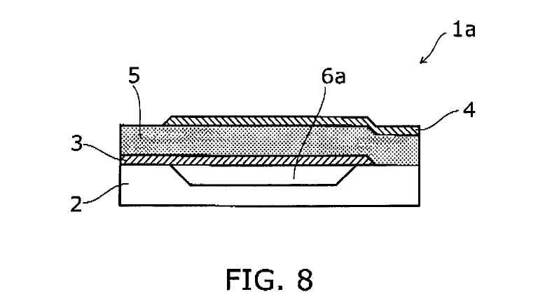

For example, the film bulk acoustic resonator 1 illustrated in the examples includes a cavity 6 passing through the substrate 2, but it is not limited thereto. As shown in FIG. 8, the film bulk acoustic resonator 1a may include a hollow cavity 6a.

The elements included in the above examples can be combined with each other as long as technically feasible, and such combinations are also encompassed within the scope of the invention as long as they include the features of the invention.

Furthermore, it is also possible to use the electrode according to the embodiment of the invention in one of the lower electrode 3 and the upper electrode 4, and to use a material having high acoustic impedance such as pure copper (Cu) or other copper alloys, molybdenum (Mo), tungsten (W), or ruthenium (Ru) in the other electrode.

The shape, dimension, material, and arrangement of the upper electrode, lower electrode, piezoelectric film, substrate, and cavity illustrated in the examples are not limited to those illustrated, but can be suitably varied.

The method for forming various films on the substrate and the etching method are not limited to the illustrated examples, but can be suitably varied.

Furthermore, the film bulk acoustic resonator can be used singly, or a plurality of the film bulk acoustic resonators can be coupled with each other, to serve as a resonator filter.

1. A film bulk acoustic resonator comprising:
a substrate;
a lower electrode held on the substrate with at least a portion thereof being in a hollow state;
a piezoelectric film provided on the lower electrode; and
an upper electrode provided on the piezoelectric film,
at least one of the lower electrode and the upper electrode being primarily composed of copper (Cu) and further containing a first element having a negatively larger free energy of oxide formation (ΔG) than copper.

2. The film bulk acoustic resonator according to claim 1, wherein the first element is at least one selected from the group consisting of aluminum (Al), titanium (Ti), zirconium (Zr), nickel (Ni), chromium (Cr), tantalum (Ta), niobium (Nb), tungsten (W), and molybdenum (Mo).

3. The film bulk acoustic resonator according to claim 1, wherein a selective oxide coating is formed on a surface of at least one of the lower electrode and the upper electrode by containing the first element.

4. The film bulk acoustic resonator according to claim 1, wherein the first element is an element forming oxygen-deficient (n-type) oxide.

5. The film bulk acoustic resonator according to claim 4, wherein the first element is at least one selected from the group consisting of aluminum (Al), titanium (Ti), zirconium (Zr), nickel (Ni), and chromium (Cr).

6. The film bulk acoustic resonator according to claim 1, wherein the first element is one of zirconium (Zr) and aluminum (Al).

7. The film bulk acoustic resonator according to claim 1, wherein content of the first element is 10 atomic percent or less.

8. The film bulk acoustic resonator according to claim 1, wherein one of the lower electrode and the upper electrode is primarily composed of copper (Cu) and contains the first element, and the other of the lower electrode and the upper electrode contains a material having an acoustic impedance not lower than acoustic impedance of copper.

9. The film bulk acoustic resonator according to claim 1, wherein one of the lower electrode and the upper electrode is primarily composed of copper (Cu) and contains the first element, and the other of the lower electrode and the upper electrode contains one selected from the group consisting of copper (Cu), a copper alloy, molybdenum (Mo), tungsten (W), and ruthenium (Ru).

10. The film bulk acoustic resonator according to claim 1, wherein the resonator further includes the second element.

11. The film bulk acoustic resonator according to claim 1, wherein the resonator further includes the first element and content of sum of the first element and the second element is 10 atomic percent or less.

12. A film bulk acoustic resonator comprising:
a substrate;
a lower electrode held on the substrate with at least a portion thereof being in a hollow state;
a piezoelectric film provided on the lower electrode; and
an upper electrode provided on the piezoelectric film,
at least one of the lower electrode and the upper electrode being primarily composed of copper (Cu) and further containing a second element having smaller surface energy than copper.

13. The film bulk acoustic resonator according to claim 12, wherein a wetting angle of at least one of the lower electrode and the upper electrode is smaller than a wetting angle of copper (Cu) by containing the second element.

14. The film bulk acoustic resonator according to claim 12, wherein the second element is at least one selected from the group consisting of zirconium (Zr), aluminum (Al), silicon (Si), and magnesium (Mg).

15. The film bulk acoustic resonator according to claim 12, wherein the second element is one of zirconium (Zr) and aluminum (Al).

16. The film bulk acoustic resonator according to claim 12, wherein content of the second element is 10 atomic percent or less.

17. The film bulk acoustic resonator according to claim 12, wherein one of the lower electrode and the upper electrode is primarily composed of copper (Cu) and contains the first element, and the other of the lower electrode and the upper electrode contains a material having an acoustic impedance not lower than acoustic impedance of copper.

18. The film bulk acoustic resonator according to claim 12, wherein one of the lower electrode and the upper electrode is primarily composed of copper (Cu) and contains the first element, and the other of the lower electrode and the upper electrode contains one selected from the group consisting of copper (Cu), a copper alloy, molybdenum (Mo), tungsten (W), and ruthenium (Ru).

19. The film bulk acoustic resonator according to claim 12, wherein the resonator further includes the first element.

20. The film bulk acoustic resonator according to claim 12, wherein the resonator further includes the second element and content of sum of the first element and the second element is atomic percent or less.
